(19) United States
(12) Patent Application Publication
(10) Pub. No.: US 2008/0273381 A1
(43) Pub. Date: Nov. 6, 2008

(54) Method for Switching Random Access Memory Elements and Magnetic Element Structures

(76) Inventor: Siu-Tat Chui, Newark, DE (US)

Correspondence Address: RATNERPRESTIA, P.O. BOX 1596, WILMINGTON, DE, 19899, US

(21) Appl. No.: 11/885,703

(22) PCT Filed: Mar. 1, 2006
(86) PCT No.: PCT/US2006/007026

§ 371 Date: May 5, 2008

Related U.S. Application Data
(60) Provisional application No. 60/656,899, filed on Mar. 1, 2005.

(51) Int. Cl. G11C 11/00

(52) U.S. Cl. 365/171

(57) ABSTRACT

A method for storing data in a magnetic memory element of an array of elements which avoids inadvertent switching of other elements. First and second magnetic fields are applied to a selected magnetic element for a first time interval to switch the element into an intermediate state where minor domains are created. A second value of magnetic fields are then applied large enough to switch the magnetization of the minor domains, but not large enough to switch the magnetization of an adjacent memory cell. Once the minor domain is switched, the magnetization of the magnetic element assumes the state where the major domain has a magnetization direction representing the value of the stored data bit.

### BACKGROUND OF THE INVENTION

The present invention relates to switching data bits in a magnetic random access memory element. Specifically, the method switches the magnetization direction of the major magnetic domain in a polycrystalline memory element to store a data bit.

The storage of data in arrays of magnetic elements is disclosed in U.S. Pat. No. 6,545,906, and U.S. Pat. No. 5,978,257, as well as other prior art references. Each of these devices have magnetic elements arranged in addressable rows and columns. Each element is generally configured as a rectangular element which has grains of magnetic material which have a randomly oriented magnetic anisotropy direction. The magnetic moments of the randomly oriented grains of a memory element arrange themselves in domains, which, in a rectangular element, tend to be oriented along the length of the element, and along the vertical height of the element. The domains of a magnetic element in an array of such elements can be initialized to have a magnetization pointing in the same direction by applying a large magnetic field at high temperatures and cooling it down. The direction of the magnetic field in the major, lengthwise domain constitutes the value of the stored bit. Thus, a zero bit could have a magnetization orientation left-to-right, and, when written with a bit 1, have a magnetization direction from right-to-left.

One of the difficulties in fabricating arrays of these magnetic elements is the inability to switch the data in one element without switching it in other elements of a row or column of elements. In order to write each element of a row/column correctly, and avoid writing to other element, a switching threshold is set so that both the writing field Hₓ or H_{y} must have a nonzero value when writing data to an element of the row. The direction of magnetization can only change if both Hₓ and H_{y} are nonzero. However, this technique to control selectivity is not available in high density MRAM arrays.

The present invention proposes a way for storing bits in the major domain of a rectangular memory element which avoids inadvertently rewriting any other elements in the row (or column) of elements.

### SUMMARY OF THE INVENTION

A method is provided for switching a magnetic element in an array of memory elements by applying a magnetic field having first and second perpendicular magnetic components to a single rectangular magnetic element. The rectangular magnetic element has a major domain along the lengthwise axis, which has a magnetization direction depending on the value of data stored. In accordance with the method, after a substantial fraction of the magnetization is rotated, the rectangular magnetic element is placed in a magnetization state where a minor domain is created along the top or bottom of the major domain representing an intermediate metastable state of the magnetic element. The magnetization direction for the major domain can then be switched by switching the magnetization of the newly created minor domain in the direction representing the value of the bit to be stored. Once the newly created minor domain, either at the top or bottom of the rectangular element, is switched, the remaining magnetization is switched, the major domain of the magnetic element assumes the magnetization direction corresponding to the value of the bit stored.

The inadvertent switching of other elements in a row/column of the array is avoided by first establishing an intermediate metastable state for the magnetic memory element during time t₀ to t₁. Once the intermediate metastable state is achieved having minor domains along the top or bottom edges of the rectangular element, the value of bits can be switched by changing the values of the magnetic write fields for a time period t₁ and t₂ to a level which establishes the final magnetization configuration for the element without switching adjacent elements of the row of elements.

A new magnetic element structure is provided by the invention which uses magnetic materials with low values of intrinsic anisotropy and high magnetization densities. These magnetic elements are generally rectangular in shape and have a thickness that can be as thick as 100-200 Angstroms, the thickness and the aspect ratio is chosen to optimize the coercivity. This structure improves the tolerance to the fluctuation of the magnetic fields to switch the major domains of these magnetic elements from bit to bit while maintaining a reasonable read efficiency. In the extreme limit of very soft materials, a single set of magnetic fields may be used.

### BRIEF DESCRIPTION OF THE DRAWINGS

FIG. 1 shows a magnetization configuration of a rectangular magnetic element with imperfect straight edges and 24 randomly oriented grains having a left-to-right magnetization direction;

FIG. 2 illustrates an intermediate metastable state for the magnetic element having an additional minor domain on the lower left edge;

FIG. 3 shows the final magnetization configuration after switching the magnetization to have a right/left orientation;

FIG. 4 represents the value of magnetic fields applied to an element for switching the element magnetization direction;

FIG. 5 shows an example of the magnetic field boundaries for creating an intermediate metastable state and for switching the intermediate metastable state minor domain magnetization direction;

FIG. 6 illustrates the magnetic field boundaries for creating and switching the minor domains for a different magnetic element material having a smaller intrinsic anisotropy;

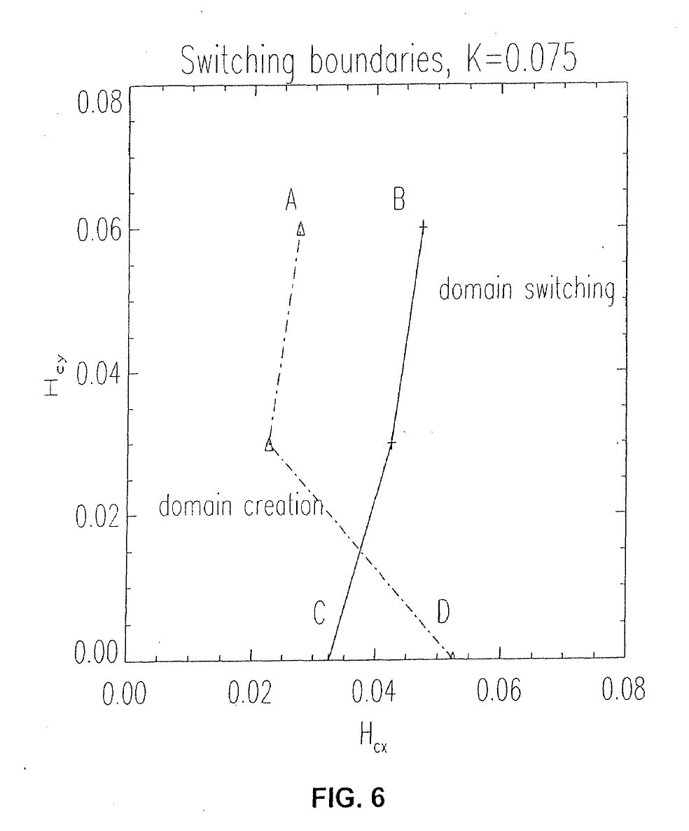

FIG. 7 illustrates the magnetic field boundaries for a magnetic memory element having zero intrinsic anisotropy K=0;

FIG. 8 shows the magnetization configuration for the creation of the horizontal minor domains;

FIG. 9 shows a magnetization configuration during the switching of the horizontal minor domain; and

FIG. 10 illustrates the structure to write and read a data bit to a magnetic memory element.

### DESCRIPTION OF THE PREFERRED EMBODIMENT

Magnetic random access memories comprise an array of individual magnetized array elements each of which can store a single bit. The array elements are organized in rows and columns which are addressable and writeable by first and second orthogonal magnetic fields. Each memory element is generally polycrystalline and has a preferred orientation of magnetization. The strength of the alignment force that aligns the magnetization for the element relative to the crystal axis is measured as the intrinsic anisotropy constant K.

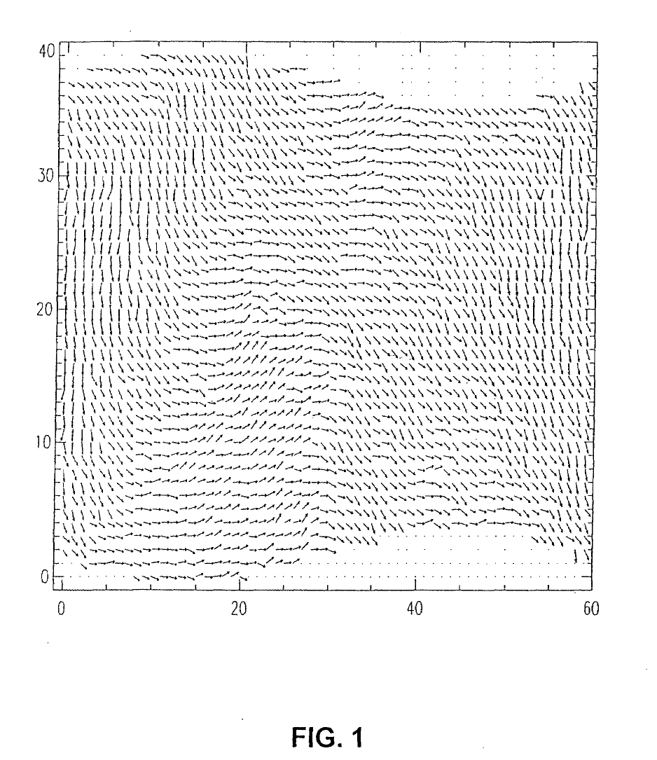

Referring to FIG. 1, the magnetization direction of a single rectangular polycrystalline element is illustrated by a series of arrows which are generally pointing from left-to-right representing a binary 0. Both the left and right side of the rectangular element have minor magnetic domains which are essentially vertical. The major magnetic domain is horizontal, along the major horizontal axis of the rectangular element.

Each of the magnetic elements can be initialized to have the vertical magnetization in the same direction by applying a large magnetic field at high temperatures, and then cooling down the element. In prior schemes, bit selectively is provided by a requirement that external first and second orthogonal magnetic fields Hₓ, H_{y} must have a nonzero value which prevents switching of the other elements of a row of magnetic storage elements.

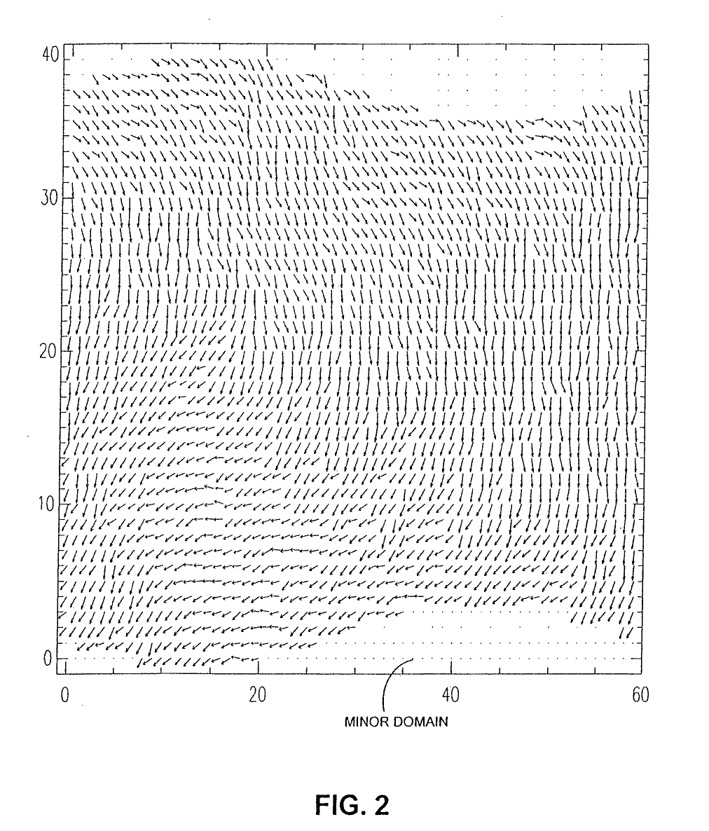

To solve the bit selectivity problem, the present invention creates an intermediate metastable magnetization configuration for the memory element using values of Hₓ, H_{y} which are too small to switch other elements. This intermediate state is illustrated in FIG. 2, which includes a minor horizontal magnetic domain shown at the bottom left portion of the magnetic element having a magnetization pointing right-to-left. The rectangular element has an aspect ratio (length/width) of approximately 1.5 and a thickness selected to reduce thermal fluctuation and produce a reasonable switching field. In the preferred embodiment, a soft magnetic film with high magnetization (for example, permador) may be selected having a length of 0.1 microns and a thickness of 100 Angstroms. As the dimensions of the magnetic element gets smaller, the thickness, preferably, should be increased inversely to the decease in length to reduce thermal fluctuation.

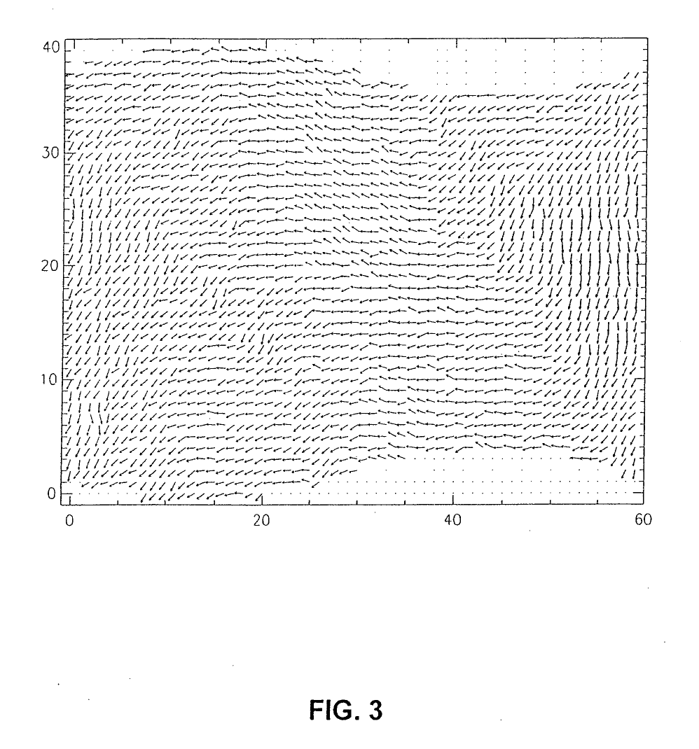

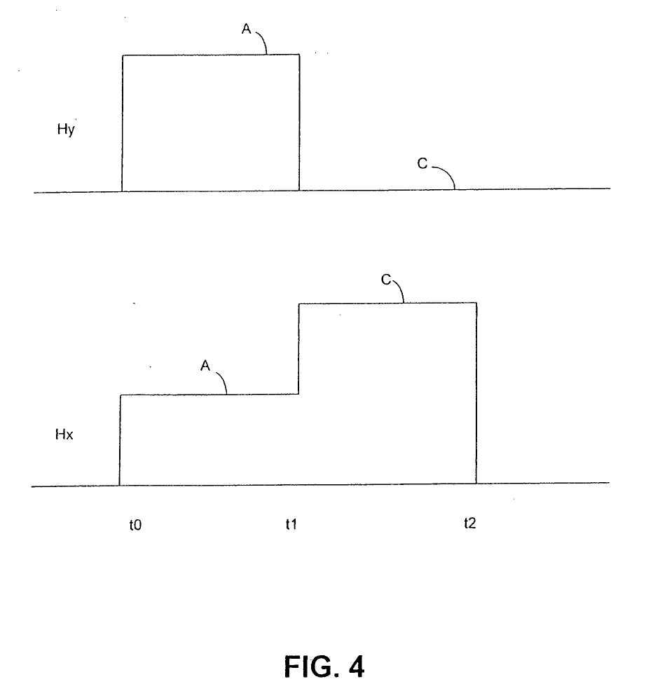

Switching into the metastable state is effected by applying the orthogonal magnetic fields H_{y} and Hₓ for an duration of t₀-t₁ as illustrated in FIG. 4. These selected magnetic fields have a direction and magnitude to create the minor domain of FIG. 2. Once the minor domain has been created, during interval t₁-t₂ the orthogonal magnetic fields H_{y} and Hₓ are changed to values which will switch the orientation of the minor domain created in the intermediate metastable state but insufficient to switch other elements. Once the magnetization direction for the minor domain is switched, the direction of magnetization for the larger domain will switch. FIG. 3 shows the magnetization direction which has been switched to right-to-left representing a binary 1.

The intermediate state can be switched with smaller fields using soft magnetic materials with a low enough intrinsic anisotropy constant K. The method presented by FIG. 4 applying magnetic fields in a two-step process for switching the direction of magnetization will be described.

The use of two different values of orthogonal magnetic components to establish an intermediate metastable state, and then switch the orientation of the magnetization of the minor domain, and hence the magnetization of the major domain of the magnetic element, avoids the necessity of using larger magnetic fields which can inadvertently switch other elements in a row/column.

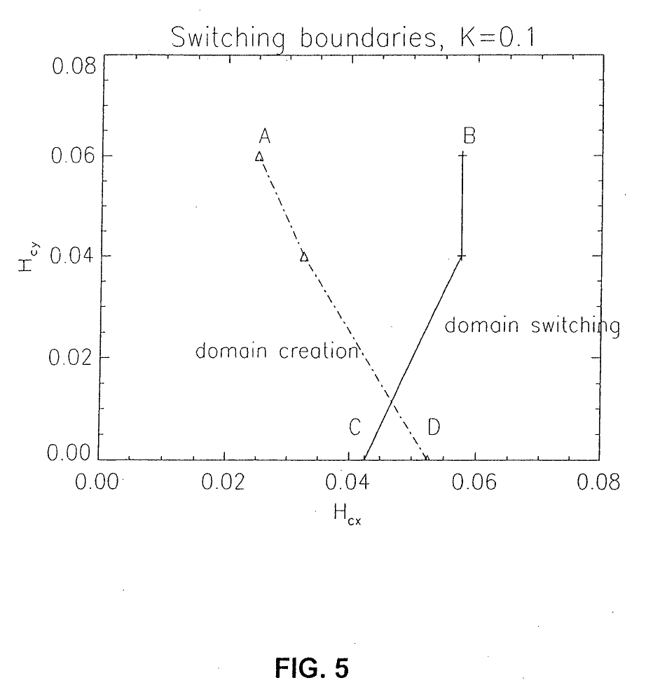

FIG. 5 illustrates an example of the boundaries for the applied magnetic fields Hₓ, H_{y} used to create the minor domains of FIG. 2, as well as the levels of magnetic fields necessary to switch the minor domain magnetization direction. The line A-D define the magnetic field strength Hₓ₁ and H_{y1} for establishing the intermediate metastable state, and line B-C represents the value of magnetic intensity to switch the minor magnetic domain after they are created. Thus, applying magnetic field values corresponding to point A for time period t₀-t₁ will create the required minor domain. The example shown in FIG. 5 represents a simulated magnetic element sample, having a magnetization density of 800 emu/cc and an exchange of 1.4×10⁻⁶ erg/cm. The length of the simulated magnetic element was 0.3 microns and the thickness was 100 Angstrom in the simulation. The magnetic field units in the figures represent 6400 G and the unit of K is 5×10⁻⁶ erg/cc.

Once the value of magnetic fields for A have been established, the resulting horizontal minor domains can be switched by selecting values of orthogonal magnetic write fields shown at C during period t₁, t₂ where C is the end of the domain switching locus B/C where H_{y}=0. Because the minor domain in the intermediate metastable state has been created, the applied magnetic field may be selected corresponding to C. This avoids the need to have a larger set of magnetic field components Hₓ, H_{y} corresponding to a point B, where the value of Hₓ is essentially that of D, which has sufficient intensity to switch other elements in the row.

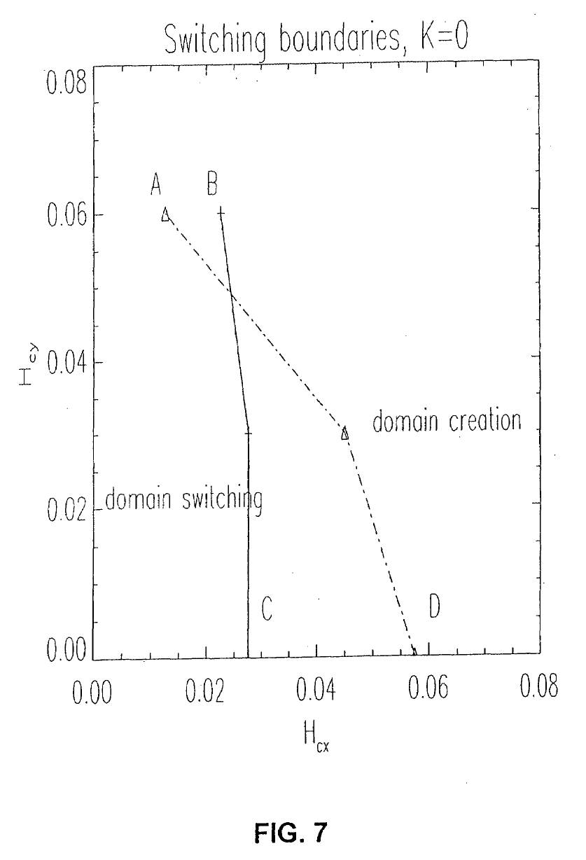

In general, selectivity is improved the greater the difference between magnetic field intensities between points C and D. FIG. 7 shows boundaries for a magnetic element having zero intrinsic anisotropy. Thus, the value of the anisotropy constant K can control the boundaries for switching the intermediate metastable state. As K decreases, the distance between C and D is increased. For the extreme case where K is equal to zero, as shown in FIG. 7, the switching field at B is much smaller than at D. A magnetic field in the Y direction makes it easier to switch the edge minor domains by selecting a value at location C on the domain switching locus B/C, and it may not be necessary to have a two-step switching process as disclosed in FIG. 4. Since the magnetic fields achieve the domain switching are much smaller than the fields to establish D, it may be possible, in a single step, to change the entire domain magnetization of the major domain.

Materials exhibiting a smaller anisotropy constant K include permalloy and an alloy of FE and CO with composition close to 60:40. Small amounts of other elements (such as Cr or B) may also be added to improve other properties (such as corrosion resistance) of the element. The permalloy material has the disadvantage, however, of having a small tunnel magneto resistance ratio which is used to detect the state of the element.

The magnetic element which has a low, K=0, intrinsic anisotropy value, can be rectangular in shape with straight edges making it easier to make. The thickness can be thicker than prior art elements, from 100 to 200 Angstroms. This reduces thermal fluctuation and has higher coercivity improving stability.

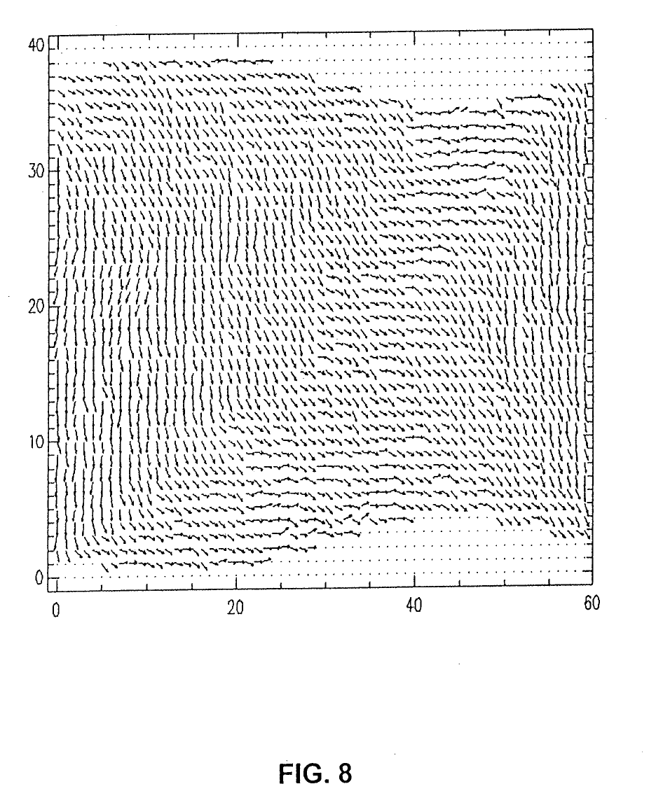

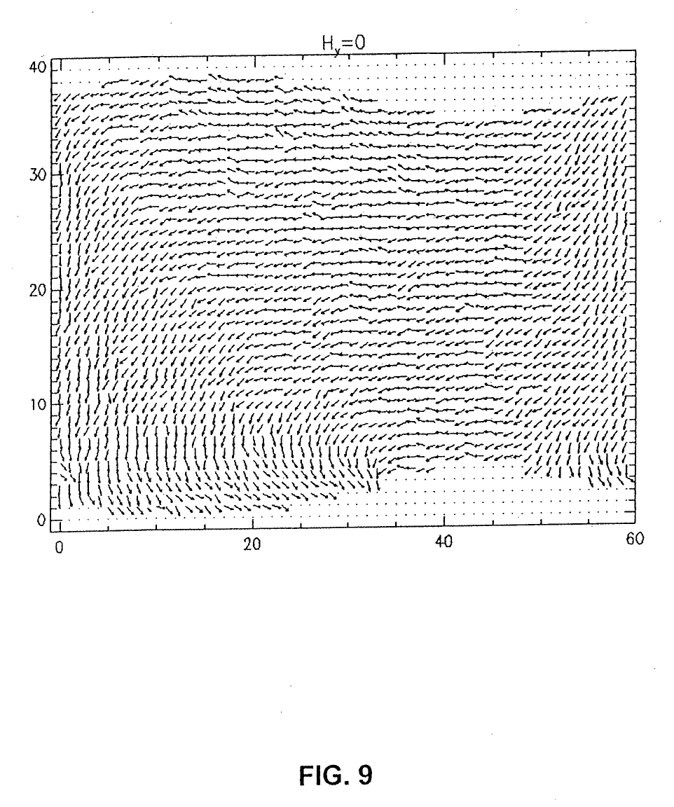

The switching process which results from the random intrinsic anisotropy of the rectangular magnetic element is shown in FIGS. 8 and 9. In FIG. 8, as the external magnetic fields Hₓ and H_{y} increase from the zero field configuration of FIG. 1, vertical minor domains on the left and right grow in size as shown in FIG. 8. When the fields are large enough, the left and right minor domains merge which determines the horizontal minor domain creation boundary of FIG. 2. In FIG. 9, a domain wall is created on the lower right hand corner in the horizontal minor domain due to the application of the magnetic field from Hₓ from t₁-t₂, the domain wall moves horizontally across the sample to create the magnetization direction represented in FIG. 3 pointing right-to-left. Since the random grain anisotropy impedes this movement of the domain wall, larger magnetic fields are required to move the defect represented by the minor domain wall across the dimensions of the rectangular element. Thus, the anisotropy constant K, while having a smaller effect in creating the minor top and bottom edge domains of FIG. 2, will affect the ability to switch the domain magnetization orientation.

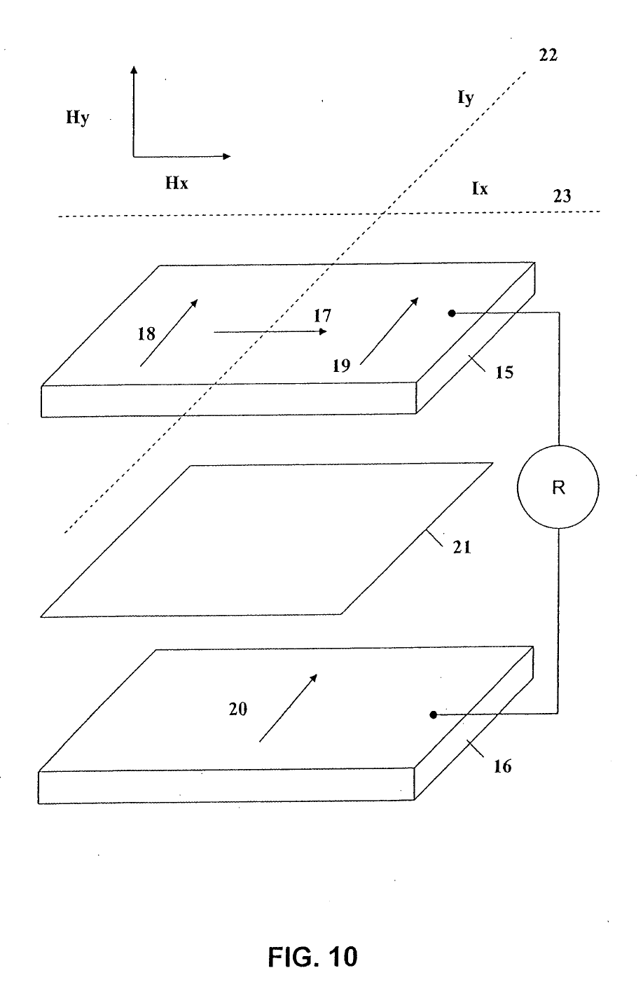

The structure of an array element with write and read capability is shown in FIG. 10. Writing data to the element requires currents Iₓ, I_{y} through row conductor 23 and column conductor 22 to have a value which produces the foregoing levels of magnetic intensity Hₓ, H_{y} to change the magnetization direction of magnetic element 15.

Reading the bit information from the magnetic element is accomplished using the tunnel magneto resistance effect. The structure of an array element is shown in FIG. 10, wherein a first metallic element 15 is separated by a thin insulating layer 21 from a separate magnetic element 16. The resistance through elements 15, 16 and insulating layer 21 represents the relative orientation of magnetization between the top and bottom layers. If the magnetization of the bottom layer 16 is fixed, the orientation of the top layer 15 can be determined by measuring the resistance through the package. Materials with larger magnetizations exhibits higher tunnel magneto resistance ratios. However, they may not have the required bit selectivity during a write operation. Accordingly, the element must be selected to provide a balance between the write process, requiring bit selectivity without affecting other memory elements, and bit readability which is essentially measured by the magneto resistance ratio between states of magnetization of the element.

The foregoing description of the invention illustrates and describes the present invention. Additionally, the disclosure shows and describes only the preferred embodiments of the invention in the context of a method for switching magnetic random access memory elements, but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form or application disclosed herein. Also, it is intended that the appended claims be construed to include alternative embodiments.

What is claimed as new and desired to be protected by Letters Patent of the United States is:

1. A method for switching a magnetic memory element comprising:
applying a magnetic field having first and second perpendicular magnetic components to a single rectangular magnetic element which has a major domain and an initial magnetization state in the direction of the major axis of said rectangular element to create a minor domain along the bottom or top of said major domain, wherein an intermediate metastable state of said magnetic element is created; and
subsequently applying a magnetic field having different first and second perpendicular magnetic components for changing the magnetization orientation of said minor domain whereby said magnetization of the major domain of said elements is reversed from said initial magnetization state.

2. A magnetic memory element comprising:
a rectangular shaped magnetic material having a low value of intrinsic anisotropy, and high magnetization, said material having a thickness of up to 100-200 Angstroms, and having relatively straight edges.
